(19) United States
(12) Patent Application Publication
(10) Pub. No.: US 2026/0273878 A1
(43) Pub. Date: Sep. 17, 2026

(54) A METHOD FOR FABRICATING AN OPTIC ELEMENT

(71) Applicants: Agency for Science, Technology and Research, Singapore (SG); National University of Singapore, Singapore (SG)

(72) Inventors: Ziyu Wang, Singapore (SG); Ramon Jose Paniagua Dominguez, Singapore (SG); Vignesh Suresh, Singapore (SG); Arseniy Kuznetsov, Singapore (SG); Deepak Kumar Sharma, Singapore (SG); Egor Khaidarov, Singapore (SG); Hailong Liu, Singapore (SG); Hong Liu, Singapore (SG); Jie Deng, Singapore (SG); Siqi Liu, Singapore (SG); Chaobin He, Singapore (SG)

(21) Appl. No.: 19/469,312

(22) PCT Filed: Mar. 25, 2024
(86) PCT No.: PCT/SG2024/050171

§ 371 Date: Sep. 25, 2025

(30) Foreign Application Priority Data
Mar. 28, 2023 (SG) 10202300848W

(51) Int. Cl. B29D 11/00; B29K 33/04; B29K 105/16; B29K 509/02; G03F 7/00

(52) U.S. Cl. CPC B29D 11/0048; G03F 7/0002; G03F 7/0005; G03F 7/70383; B29K 2033/04; B29K 2105/162; B29K 2509/02

(57) ABSTRACT

A method for fabricating an optic element The method may include: fabricating a first mold having a pattern of the optic element; fabricating a second mold with a soft material by using the first mold, the second mold having an opposite pattern to the pattern of the optic element; forming a nanocomposite layer on a substrate, where the nanocomposite layer comprises nanoparticles embedded therein, the nanocomposite layer having a refractive index which is equal to or greater than 2; placing the second mold onto the nanocomposite layer and curing the nanocomposite layer; and demolding the cured nanocomposite layer from the second mold to obtain the optic element.

### TECHNICAL FIELD

The present disclosure generally relates to a method for fabricating an optic element, in particular, a method for fabricating metalenses.

### BACKGROUND

Compared to traditional bulky lenses, metalenses are lightweight, ultrathin, CMOS compatible, and integrable with optoelectronic components. They have attracted much attention for their unique properties. The conventional methods for fabricating metalenses commonly utilize the electron-beam lithography (EBL) followed by the dry etching method to form meta-atoms employed to control the phase delay of incidence light accurately. However, those approaches are not scalable for mass production due to the limitation of the EBL, which hinders the commercialization progress of the metalens technology.

Therefore, there exists a need to provide high throughput and large area fabrication processes to make flat optics and metalenses in the industry, particularly in light detection and ranging (LiDAR), Augmented Reality (AR)/Virtual Reality (VR), smartphone camera modules, etc.

### SUMMARY

According to a first aspect of the present disclosure, a method for fabricating an optic element is provided. The method may include: fabricating a first mold having a pattern of the optic element; fabricating a second mold with a soft material by using the first mold, the second mold having an opposite pattern to the pattern of the optic element; forming a nanocomposite layer on a substrate, wherein the nanocomposite layer comprises nanoparticles embedded therein, the nanocomposite layer having a refractive index which is equal to or greater than 2; placing the second mold onto the nanocomposite layer and curing the nanocomposite layer; demolding the cured nanocomposite layer from the second mold to obtain the optic element.

### BRIEF DESCRIPTION OF THE DRAWINGS

FIG. 1 is a flowchart showing a method for fabricating an optic element (e.g. a metalens) according to various embodiments of the present disclosure.

FIG. 2 is a block diagram depicting a method for fabricating a flat optic element (e.g. a metalens) according to various embodiments of the present disclosure.

FIG. 3A and FIG. 3B show an optical microscopy and SEM characterization of a (silicon) master mold, respectively, according to various embodiments of the present disclosure.

FIG. 3C shows an optical microscopy characterization of a soft mold fabricated using EVGNIL UV/AF1 as a soft material according to various embodiments of the present disclosure.

FIG. 3D and FIG. 3E show an SEM characterization of the soft mold fabricated using EVGNIL UV/AF1 as the soft material of FIG. 3C.

FIG. 3F show an optical microscopy characterization of a metalens fabricated using TiO₂ nanoparticle embedded acrylic resin nanocomposite as a nanocomposite material according to various embodiments of the present disclosure.

FIG. 3G to 3J show an SEM characterization of a metalens fabricated using TiO₂ nanoparticle embedded acrylic resin nanocomposite as a nanocomposite material according to various embodiments of the present disclosure.

FIG. 3K show a refractive index of the TiO₂ nanoparticle embedded acrylic resin nanocomposite as a function of the wavelength.

FIG. 4A and FIG. 4B show optical characterization of a master mold according to various embodiments of the present disclosure.

FIG. 4C and FIG. 4D show optical characterization of a soft mold fabricated using GMN-PS380 as a soft material according to various embodiments of the present disclosure.

FIG. 4E and FIG. 4F show a respective reflection optical micrograph and a transmission optical micrograph of a metalens fabricated using TiO₂ nanoparticle embedded IOC-133 resin nanocomposite as a nanocomposite material according to various embodiments of the present disclosure.

FIG. 5 shows phase shift and transmission of unit cells of a designed metalens as a function of diameters of the unit cells according to various embodiments of the present disclosure, where a unit cell (i.e., nanopillar) of the metalens is shown in the inset of FIG. 5.

FIG. 6 shows point spread function (PSF) of a designed optic element for simulating focusing efficiency, according to various embodiments of the present disclosure.

FIGS. 7 to 9 respectively show optical characterization results of focusing efficiency, full width at half maximum (FWHM), and focal length of a metalens fabricated in accordance with the methods of the present disclosure.

### DETAILED DESCRIPTION

Embodiments described below in the context of a method are analogously valid for the respective element, device, apparatus, or system, and vice versa. Furthermore, it will be understood that the embodiments described below may be combined, for example, a part of one embodiment may be combined with a part of another embodiment, and a part of one implementation may be combined with a part of another implementation.

It should be understood that the singular terms “a”, “an”, and “the” include plural references unless context clearly indicates otherwise. Similarly, the word “or” is intended to include “and” unless the context clearly indicates otherwise.

It will be further understood that the terms “comprise” (and any form of comprise, such as “comprises” and “comprising”), “have” (and any form of have, such as “has” and “having”), “include” (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

Approximating language, as used herein throughout the specification and claims, may be applied to modify any quantitative representation that could permissibly vary without resulting in a change in the basic function to which it is related. Accordingly, a value modified by a term or terms, such as “about,” “substantially”, is not limited to the precise value specified but within tolerances that are acceptable for operation of the embodiment for an application for which it is intended. In some instances, the approximating language may correspond to the precision of an instrument for measuring the value.

The term “mold” may be used herein to mean a tool or template or stamp used in a fabrication process (i.e. a molding process) to shape or form materials corresponding to a desired pattern or model specification of a final product. A mold may typically have a cavity (e.g. gap) that defines the external shape of the product and a core that defines internal features of the product. A mold may be used repeatedly for a large number of production cycles.

The term “optic element” may be used herein to mean any component or device that interacts with light for the purpose of manipulating or controlling its properties. Optic elements may be used in various fields, including optics, photonics, imaging, and telecommunications. An optic element may include a metalens, and/or a component of the metalens.

The term “metalens” may be used herein to mean a type of lens that uses nanoscale structures, often made of metamaterials or nanostructures, to control the phase and amplitude of light at the subwavelength scale. Unlike traditional lenses, which are made of bulk materials and rely on curved surfaces to refract light, metalenses may utilize engineered patterns at the nanoscale to achieve specific optical properties. Metalenses have gained significant attention in the field of optics and photonics due to their potential for compact size, lightweight design, and the ability to overcome some limitations of conventional lenses.

As used herein, the term “pattern” may refer to the specific arrangement and design of nanoscale structures (e.g. concentric circles, gratings, or other geometric configurations) on the surface of an optic element (e.g. a metalens). Metalenses may utilize these patterns to control the phase and amplitude of light, allowing for precise manipulation of light waves at the subwavelength scale. The patterns on a metalens may play a crucial role in determining its optical properties and performance.

As used herein, the term “opposite pattern” may refer to a reversal or inversion of a given pattern. This may involve inverting the elements of the pattern to create a reversed version. In the context of various embodiments, the pattern and the opposite pattern may refer to two patterns supplementary to each other in a manner that a profile (e.g. outline, configuration) of the pattern conforms (e.g. match) to a profile (e.g. outline, configuration) of the opposite pattern in an inverted way. For example, in the context of a flat optic element, a protrusion in the pattern corresponds to a recess in the opposite pattern such that the protrusion fits closely in the recess.

As used herein, the term “nanoimprinting” may refer to a nanofabrication technique used to create patterns and structures at the nanoscale by replicating nanoscale features from a mold onto a target material. Ultraviolet (UV) nanoimprint lithography may involve using a transparent mold with a nanoscale relief pattern. The mold may be brought into contact with a UV-curable resin on a substrate. The resin may be then cured using UV light, creating a replica of the mold pattern on the substrate.

As used herein, the term “resin” may broadly refer to a class of synthetic or naturally occurring compounds that are typically viscous and may harden into a solid or semi-solid state. A resin may include a polymer resin, a thermosetting resin, a thermoplastic resin, a UV-curable resin and the like. A UV-curable resin may cure or harden when exposed to UV light. In the context of nanoimprinting, resins may be used as a material for the imprinting process.

As used herein, the term “resist” may refer to, in the context of lithography, a light-sensitive material that is used as a coating on a substrate to create patterns. The resist may undergo chemical or physical changes when exposed to light, and this property may be utilized in processes like photolithography. A resin may include a resist for utilization in photolithograph.

As used herein, the term “soft material” may refer to materials that may be easily deformed by thermal stresses or thermal fluctuations at about room temperature, including liquids, polymers, foams, gels, colloids, granular materials, and the like. Particularly, the soft material may include a UV-curable resin (e.g. polymer stamp materials such as EVGNIL UV/AF1 or GMN-PS380), a photo-curable resin or a thermal-curable resin. UV-curable resin may include a UV-curable fluoropolymer. EVGNIL UV/AF1 or GMN-PS380 may be a promising polymer material for nanoimprint lithography, offering good performance in terms of surface morphology and high-resolution pattern transfer.

As used herein, the term “nanocomposite” may refer to a material that incorporates nanoparticles into a matrix to enhance or modify its properties. Nanocomposites are a type of composite material where the reinforcing phase consists of nanoparticles, which are particles with dimensions in the nanometer scale (typically 1 to 100 nanometers). In the context of various embodiments, the nanoparticles may be composed of various materials, such as metals, ceramics, polymers, or titanium-based materials like titanium dioxide. According to various non-limiting embodiments, a large-area high-resolution (<100 nm) fabrication process is presented including nanoimprinting lithography (NIL), which may make flat optical components/optical element. The fabrication may allow for precise control over the size, shape, and placement of features and be generally scalable to larger production volumes. This present approach may offer a cost-effective solution for mass production of flat optics to address the industry's needs. The present method may involve nanoimprinting lithography (NIL) to create well-defined nanopillars on a substrate.

Various embodiments of the present disclosure seek to provide a method for fabricating an optic element (e.g. a metalens). The method may include fabrication of a first mold (or referred to as master mold) via electron beam lithography (EBL) and dry etching. The master mold may have a pattern of the optic element.

The method may further include fabrication of a second mold (or referred to as soft mold) with a soft material by using the master mold, the soft mold having an opposite pattern to the pattern of the optic element. A soft material layer comprising the soft material may be patterned via nanoimprinting by the master mold to obtain the soft mold.

The method may also include fabrication of the optic element with nanocomposite material by using the soft mold. A nanocomposite layer including the nanocomposite material may be patterned via nanoimprinting by the soft mold to obtain the optic element.

The method may fabricate a master mold and a soft mold, and the soft mold may be repeatedly used to obtain optic elements (e.g. metalenses) by the process as described herein. Hence, the method may be scalable and versatile for high-volume manufacturing of optic element/flat optical components.

The method in the present disclosure advantageously and efficiently provides an optic element (e.g. a metalens) with high aspect ratio. Furthermore, the method in the present disclosure may advantageously and efficiently fabricate optic element at a wafer level via cost-effective nanoimprinting process, which is scalable for mass production of optic element. The method in the present disclosure can fabricate a single device including multiple metalenses, each of which has a different pattern catered for a different function (e.g. a different phase shift). It may address the industry needs for multifunctional flat optics for applications in light detection and ranging (LiDAR), Augmented Reality (AR)/Virtual Reality (VR), smartphone camera modules, optical imaging, miniaturized optical microscope, microspectrometer, etc.

In various embodiments, the soft material may include an ultraviolet (UV) curable photoinitiator material. The ultraviolet (UV) curable photoinitiator material may contribute to rapid fabrication of the soft mold. The soft material may include polymer stamp materials such as EVGNIL UV/AF1 or GMN-PS380.

In various embodiments, the nanocomposite layer may have a refractive index which is equal to or greater than 2. The nanocomposite material included in the nanocomposite layer may comprise titanium dioxide (TiO₂) nanoparticle embedded resin nanocomposites.

As the method includes patterning a nanocomposite layer via nanoimprinting by the soft mold to obtain the optic element, compatibility may be considered when selecting the soft material for the soft mold and the nanocomposite material for the nanocomposite layer in a manner that they are compatible to facilitate smooth demolding between the soft mold and the nanocomposite layer (e.g. thereby achieving substantially vertical walls of the patterned nanocomposite layer, i.e. high aspect ratio).

The following examples pertain to various aspects of the present disclosure.

Example 1 is a method for fabricating an optic element, including: fabricating a first mold having a pattern of the optic element; fabricating a second mold with a soft material by using the first mold, the second mold having an opposite pattern to the pattern of the optic element; forming a nanocomposite layer on a substrate, wherein the nanocomposite layer comprises nanoparticles embedded therein, the nanocomposite layer having a refractive index which is equal to or greater than 2; placing the second mold onto the nanocomposite layer and curing the nanocomposite layer; demolding the cured nanocomposite layer from the second mold to obtain the optic element.

In Example 2, the subject matter of Example 1 may optionally include that fabricating a first mold having a pattern of the optic element includes: applying an etch mask layer on a wafer; patterning the etch mask layer by electron-beam lithography to form the pattern of the optic element on the etch mask layer; and etching the wafer through the patterned etch mask layer by deep reactive-ion etching (DRIE) to form the pattern of the optic element in the wafer as the first mold.

In Example 3, the subject matter of Example 2 may optionally include that the etch mask layer includes hydrogen silsesquioxane (HSQ), a NEB-22 resist by Sumitomo Chemical, an AR-N 7520 resist by ALLRESIST GmbH, a maN resist by micro resist technology GmbH or a ZEP resist by Zeon Corporation.

In Example 4, the subject matter of Example 1 may optionally include that fabricating a second mold with a soft material by using the first mold includes: forming a soft material layer on a stamping substrate, wherein the soft material layer comprises the soft material; placing the first mold onto the soft material layer and curing the soft material layer; and demolding the cured soft material layer from the first mold to obtain the second mold.

In Example 5, the subject matter of Example 4 may optionally include that fabricating a second mold with a soft material by using the first mold further includes: applying pressure on the first mold when the first mold is placed onto the soft material layer.

In Example 6, the subject matter of Example 4 may optionally include that forming a soft material layer on a stamping substrate includes: forming a first adhesion layer on the stamping substrate; and forming the soft material layer on the first adhesion layer.

In Example 7, the subject matter of Example 1 may optionally include that the soft material includes an UV curable photoinitiator material.

In Example 8, the subject matter of Example 1 may optionally include that the soft material includes EVGNIL UV/AF1 or GMN-PS380.

In Example 9, the subject matter of Example 1 may optionally include that forming a nanocomposite layer on a substrate includes: forming a second adhesion layer on the substrate; and forming the nanocomposite layer on the second adhesion layer.

In Example 10, the subject matter of Example 1 may optionally include that the nanocomposite layer includes titanium dioxide (TiO₂) nanoparticle embedded resin nanocomposites.

In Example 11, the subject matter of Example 10 may optionally include that the titanium dioxide (TiO₂) nanoparticle embedded resin nanocomposites have a TiO₂ weight ratio ranging from 75% to 80%.

In Example 12, the subject matter of Example 1 may optionally include that the nanocomposite layer is UV curable.

In Example 13, the subject matter of Example 1 may optionally include applying pressure on the second mold when the second mold is placed onto the nanocomposite layer.

In Example 14, the subject matter of Example 1 may optionally include that the optic element includes a plurality of nanopillars having an aspect ratio which is equal to or greater than 5 to 1.

In Example 15, the subject matter of Example 14 may optionally include that a feature resolution of the plurality of nanopillars is equal to or less than 100 nm.

In Example 16, the subject matter of Example 14 may optionally include that the plurality of nanopillars has a height ranging from 500 nm to 1200 nm.

In Example 17, the subject matter of Example 14 may optionally include that the plurality of nanopillars is periodically repeated along a surface in two orthogonal directions.

In Example 18, the subject matter of Example 17 may optionally include that the periodically repeated nanopillars has a period ranging from 200 nm to 600 nm.

In Example 19, the subject matter of Example 14 may optionally include that the plurality of nanopillars has a diameter ranging from 50 nm to 400 nm.

In Example 20, the subject matter of Example 1 may optionally include repeating the steps (iii) to (v) to fabricate a plurality of the optic elements having the pattern.

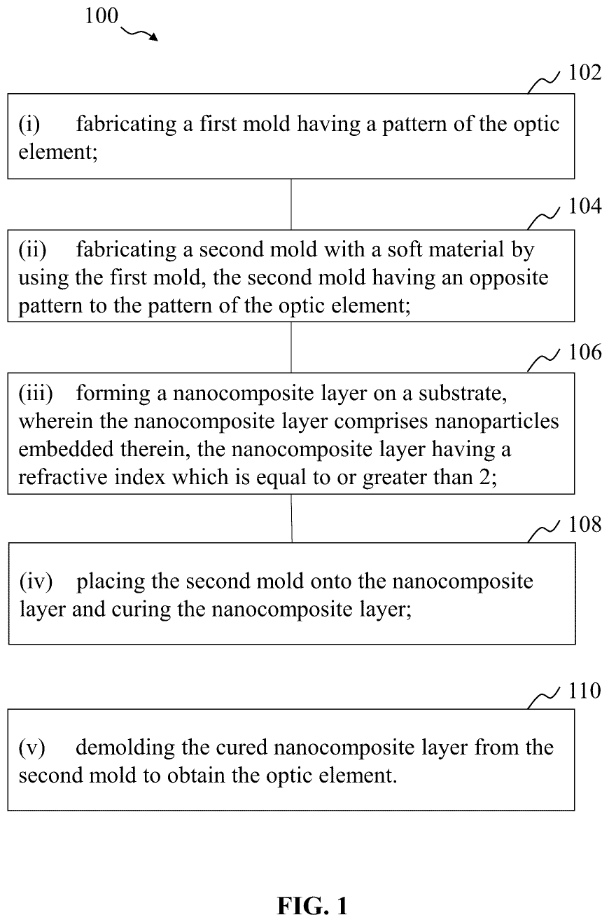

FIG. 1 is a flowchart showing a method 100 for fabricating an optic element (e.g. a metalens) according to various embodiments of the present disclosure. The method 100 may include: at step 102, (i) fabricating a first mold (or referred to as master mold) having a pattern of the optic element; at step 104, (ii) fabricating a second mold (or referred to as soft mold) with a soft material by using the master mold, the soft mold having an opposite pattern to the pattern of the optic element; at step 106, (iii) forming a nanocomposite layer on a substrate, wherein the nanocomposite layer includes nanoparticles embedded therein, the nanocomposite layer having a refractive index which is equal to or greater than 2; at step 108, (iv) placing the soft mold onto the nanocomposite layer and curing the nanocomposite layer; at step 110, (v) demolding the cured nanocomposite layer from the soft mold to obtain the optic element.

In some embodiments, the master mold may be fabricated by: applying an etch mask layer on a wafer; patterning the etch mask layer by electron-beam lithography to form the pattern of the optic element on the etch mask layer; and etching the wafer through the patterned etch mask layer by deep reactive-ion etching (DRIE) to form the pattern of the optic element in the wafer as the master mold. It should be appreciated that the method of fabricating the master mold is not limited to the above, other known methods for fabricating the master mold are also included in the present method 100. The wafer may include a silicon wafer (e.g. silicon on silicon dioxide) typically made from a single crystal or polycrystalline silicon. The diameters of the wafer may include 100 mm (4 inches), 150 mm (6 inches), 200 mm (8 inches), 300 mm (12 inches) and any available diameter of wafers, and the thickness of the wafer may include, but not be limited to, a range from around 200 to 1000 micrometers.

According to various non-limiting embodiments, the etch mask layer may include a resist selected from hydrogen silsesquioxane (HSQ), a NEB-22 resist by Sumitomo Chemical, an AR-N 7520 resist by ALLRESIST GmbH, a maN resist by micro resist technology GmbH and a ZEP resist by Zeon Corporation.

According to various non-limiting embodiments, the soft mold may be fabricated by: forming a soft material layer on a stamping substrate, wherein the soft material layer includes the soft material; placing the master mold onto the soft material layer and curing the soft material layer; and demolding the cured soft material layer from the master mold to obtain the soft mold. The pattern may be transferred from the master mold to the demolded cured soft material layer (i.e., the soft mold) in an inverted way. In other words, the soft mold may have an opposite pattern to the pattern of the master mold. According to various non-limiting embodiments, the method 100 may further include applying pressure on the master mold when the master mold is placed onto the soft material layer. Forming a soft material layer on a stamping substrate may include forming a first adhesion layer on the stamping substrate; and forming the soft material layer on the first adhesion layer.

According to various non-limiting embodiments, the soft mold may be fabricated by dropping cast a soft material onto the master mold; and applying UV nanoimprinting process to transfer the opposite pattern to the soft material to obtain the soft mold. In other words, the soft material may be disposed on the master mold in a manner that the soft material fills (e.g. recesses of) the master mold to form the soft mold having the opposite pattern to the pattern of the optic element. Accordingly, the soft mold formed by the soft material may have a profile (e.g. outline, configuration) matching a profile (e.g. outline, configuration) of the master mold in an inverted way. According to various non-limiting embodiments, the method 100 may further include applying pressure on the drop-casted soft material using a stamping substrate with a first adhesion layer thereon being in contact with the drop-casted soft material. The soft material may be pressed by the stamping substrate to substantially or fully fill the master mold so as to form the soft mold having the opposite pattern to the pattern of the optic element.

Similarly as the method of fabricating the master mold, it should be appreciated that the method of fabricating the soft mold is not limited to the above, other known methods for fabricating the soft mold by using the master mold are also included in the present method 100.

According to various non-limiting embodiments, the optic element (e.g. the metalens) may be fabricated by: forming a nanocomposite layer on a substrate, wherein the nanocomposite layer includes the nanocomposite material; placing the soft mold onto the nanocomposite layer and curing the nanocomposite layer; and demolding the cured nanocomposite layer from the soft mold to obtain the optic element. The pattern may be transferred from the soft mold to the demolded cured nanocomposite layer (i.e., the optic element) in an inverted way. According to various non-limiting embodiments, the method 100 may further include applying pressure on the soft mold when the soft mold is placed onto the nanocomposite layer. Forming a nanocomposite layer on a substrate may include forming a second adhesion layer on the substrate; and forming the nanocomposite layer on the second adhesion layer.

According to various non-limiting embodiments, the optic element (e.g. metalens) may be fabricated by dropping cast a nanocomposite material onto the soft mold; and applying UV nanoimprinting process to transfer the pattern of the optic element to the nanocomposite material to obtain the optic element. In other words, the nanocomposite material may be disposed on the soft mold in a manner that the nanocomposite material fills (e.g. recesses of) the soft mold to form the pattern of the optic element. Accordingly, the optic element formed by the nanocomposite material may have a profile (e.g. outline, configuration) matching a profile (e.g. outline, configuration) of the soft mold in an inverted way. According to various non-limiting embodiments, the method 100 may further include applying pressure on the drop-casted nanocomposite material using a substrate with a second adhesion layer thereon being in contact with the drop-casted nanocomposite material. The nanocomposite material may be pressed by the substrate to substantially or fully fill the soft mold so as to form the pattern of the optic element.

The nanocomposite material may include dielectric nanoparticle inclusion in a matrix of UV-curable resin. The UV-curable resin may be used as a matrix material to enable the nanoimprinting of the opposite pattern of the soft mold, and the dielectric nanoparticles (e.g., TiO₂ nanoparticles) may be embedded in the matrix of UV-curable resin to increase the effective refractive index of the nanocomposite material.

According to various non-limiting embodiments, the method 100 may include repeating the steps (iii) to (v) to form a plurality of the optic elements having the pattern. Alternatively or additionally, a plurality of optic elements may be simultaneously fabricated on a substrate using a plurality of soft molds, each of the soft molds may include a different pattern according to a different requirement.

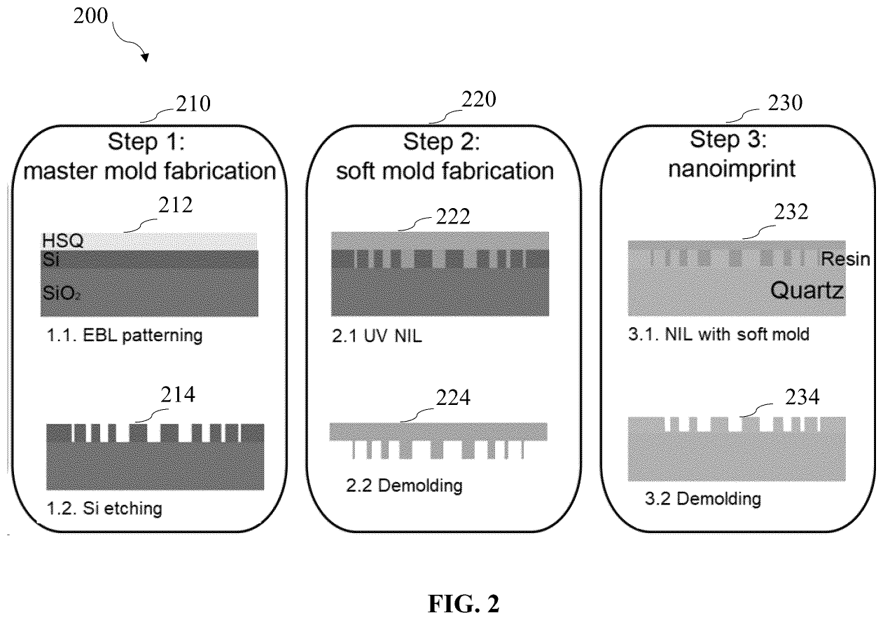

FIG. 2 is a block diagram depicting a method 200 for fabricating a flat optic element (e.g. a metalens) according to various embodiments of the present disclosure.

The method 200 may include similar steps of the method 100 as described above in connection to FIG. 1, and therefore, features that are described in the context of the method 100 may correspondingly be applicable to the same or similar features in the method 200 and vice versa. Furthermore, additions and/or combinations and/or alternatives as described for a feature in the context of the method 100 may correspondingly be applicable to the same or similar feature in the method 200 and vice versa.

According to various non-limiting embodiments, the method 200 may include Step 1, fabricating a master mold 210; Step 2, fabricating a soft mold by using the master mold 220; and Step 3, fabricating an optic element (e.g. a metalens) by using the soft mold 230. The optic element (e.g. the metalens) may have a diameter of 200 μm. The details of the above three steps will be described as follows.

### Step 1, Fabricating a Master Mold 210

A pattern of an optic element (or referred to as flat lens pattern) may be obtained by using the electron-beam lithography (EBL) (Elionix ELS-7000) with hydrogen silsesquioxane (HSQ) as an etch mask for pattern transfer from the HSQ to a wafer (e.g. silicon on silicon dioxide). The HSQ may be used to obtain the master mold having nanopillars with high aspect ratio. The nanopillars may have varying diameters. The master mold with high resolution (<100 nm) can be fabricated in large scale using high-speed EBL.

At step 212, HSQ solution may be spin-coated on a (silicon) wafer at a speed of 500 rpm for 60 s, giving rise to a thickness of about 230 nm; a designed layout (i.e. the pattern) of the flat optic element may be patterned on the HSQ by e-beam at an acceleration voltage of 100 kV and a dose of 7600 μC/cm². The HSQ may be developed in salty developer (KOH 1%, NaCl 4%, deionized (DI) water 95%) for 60 s and rinsed with DI water for 60 s to form the etch mask. Experimental parameters are provided as a reference for the present method 200 and should not be used to limit the present method 200. It should be appreciated that known methods with different experimental parameters are included in the method 200.

At step 214, the (silicon) master mold with the pattern of the optic element (or referred to as designed flat lens pattern) may be produced using the deep reactive-ion etching (DRIE) process (Oxford Plasmalab 100) through the HSQ etch mask on the (silicon) wafer. The DRIE process with a controlled mixture of HBr (50 sccm) and O₂ (3 sccm) gas, pressure of 5 mT, RIE power of 150 W, ICP of power 800 W, for 320 s may be used to attain smooth and controllable sidewalls of the resultant flat lens pattern. The remaining HSQ layer (i.e. the remaining HSQ etch mask) may be removed chemically by dipping samples in buffered hydrofluoric (HF) solution for 2 minutes. The master mold may be formed from the (silicon) wafer with nanopillars having high aspect ratio.

### Step 2, Fabricating a Soft Mold by Using the Master Mold 220

The pattern from the (silicon) master mold may be transferred to the soft mold in an inverted way, which may be used repeatedly for the subsequent nanoimprint lithography (NIL) process. The soft mold may have the opposite pattern to the pattern of the optic element (i.e. the pattern of the master mold).

At step 222, the (silicon) master mold composed of the (silicon) nanopillars as fabricated in Step 1 may be employed as the master mold. A UV-curable resin (e.g. polymer stamp materials such as EVGNIL UV/AF1 or GMN-PS380) may be employed as the soft material.

EVGNIL UV/AF1 or GMN-PS380, used as the soft material, may be drop-casted and spin-coated on a stamping substrate (e.g., quartz wafer, or referred to as quartz substrate) to form a soft material layer on the stamping substrate.

Alternatively, mr-APS1 may be spin-coated on a stamping substrate (e.g., quartz wafer, or referred to as quartz substrate) as the first adhesion layer at a spin speed of 3000 rpm for 40 s. EVGNIL UV/AF1 or GMN-PS380, used as the soft material, may be drop-casted and spin-coated on the first adhesion layer on the stamping substrate to form a soft material layer on the stamping substrate.

The (silicon) master mold may be put atop the soft material layer comprising the soft material. The UV-curable resin may fill the (silicon) master mold so as to form a soft mold having an opposite pattern to the pattern of the master mold. In other words, the UV-curable resin may fill gaps between the nanopillars of the master mold so as to form a soft mold having an opposite pattern to the pattern of the master mold.

For an example where EVGNIL UV/AF1 is used as the soft material, after the (silicon) master mold is put atop the soft material layer, UV curing of 360 s (in 5 s On/Off cycle) may be applied to solidify the soft material in the soft material layer. No external pressure may be applied.

For an example where GMN-PS380 is used as the soft material, after the (silicon) master mold is put atop the soft material layer, UV curing of 600 s (in 5 s On/Off cycle) may be applied to solidify the soft material in the soft material layer. The pressure applied on the master mold when the master mold is placed atop the soft material may be set as 20 bar.

At step 224, after curing, the cured soft material layer may be demolded from the (silicon) master mold to obtain the soft mold.

### Step 3, Fabricating a Metalens by Using the Soft Mold 230

The opposite pattern from the soft mold may be transferred to the optic element in an inverted way.

At step 232, the soft mold fabricated in Step 2 may be employed as the soft mold. A nanoparticle embedded resin nanocomposite (e.g., TiO₂ nanoparticle embedded resin nanocomposite) may be employed as the nanocomposite material.

The TiO₂ nanoparticle embedded resin nanocomposite may be prepared by mixing the TiO₂ nanoparticle dispersion (e.g., titanium dioxide (TiO₂) nanoparticles (LTPF) (e.g. with mean particle diameters of 20 nm) with acrylic polymer trimethylolpropane triacrylate and photoinitiator diphenyl(2,4,6-trimethylbenzoyl)phosphine oxide.

The TiO₂ nanoparticle embedded resin nanocomposites may have a TiO₂ weight ratio of 75% to 80%. The refractive index of the TiO₂ nanoparticle embedded resin nanocomposites may become higher when the weight ratio of TiO₂ nanoparticles increases.

The nanocomposite material may be drop-casted and spin-coated on a substrate (e.g., a quartz wafer, or referred to as a quartz substrate) to form a nanocomposite layer on the substrate.

Alternatively, mr-APS1 may be spin-coated on a substrate (e.g., a quartz wafer, or referred to as a quartz substrate) as a second adhesion layer at a spin speed of 3000 rpm for 40 s. The nanocomposite material may be drop-casted and spin-coated on the second adhesion layer on the substrate to form a nanocomposite layer on the substrate.

The soft mold may be placed atop the nanocomposite layer comprising the nanocomposite material. After placing the soft mold atop the nanocomposite layer, UV curing of 360 s (in 5 s On/Off cycle) may be applied to solidify the nanocomposite material in the nanocomposite layer. The pressure applied on the soft mold when the soft mold is placed atop the nanocomposite layer may be set to 1.0 Bar.

At step 234, after curing, the cured nanocomposite layer may be demolded from the soft mold to obtain the optic element (e.g., the metalens).

According to various non-limiting embodiments, the soft mold obtained at step 224 may be repeatedly applied to obtain a plurality of optic elements. That is, Step 3 as shown in FIG. 2 may be repeated to obtain a plurality of optic elements (i.e. metalenses). In some embodiments, a plurality of soft molds may be fabricated with varying parameters (e.g. periods, diameters of nanopillars) and the plurality of soft molds may be applied simultaneously to obtain metalenses with the varying parameters and/or periods.

While the method described above is illustrated and described as a series of steps or events, it will be appreciated that any ordering of such steps or events are not to be interpreted in a limiting sense. For example, some steps may occur in different orders and/or concurrently with other steps or events apart from those illustrated and/or described herein. In addition, not all illustrated steps may be required to implement one or more aspects or embodiments described herein. Also, one or more of the steps depicted herein may be carried out in one or more separate acts and/or phases.

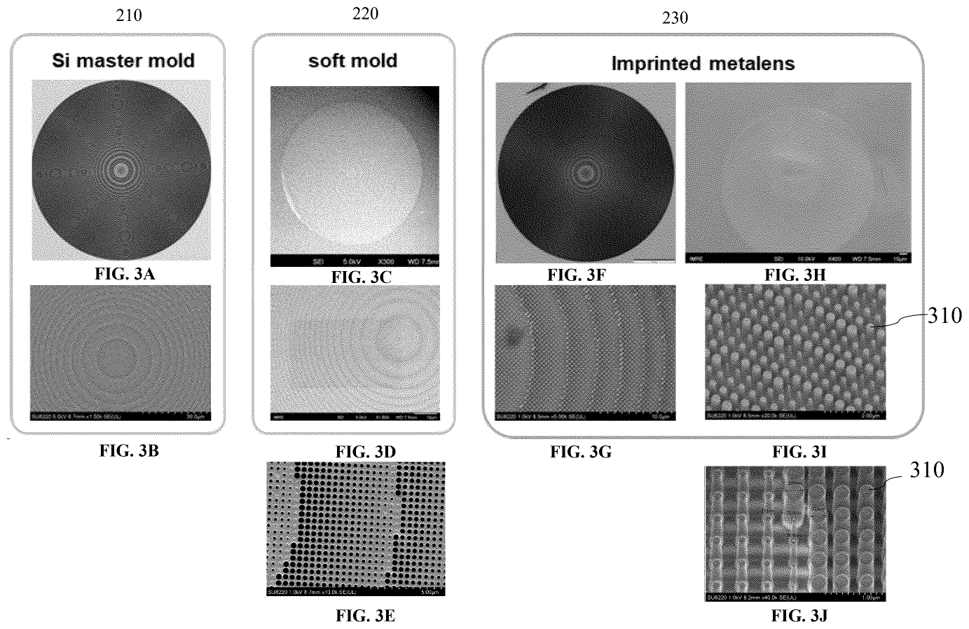

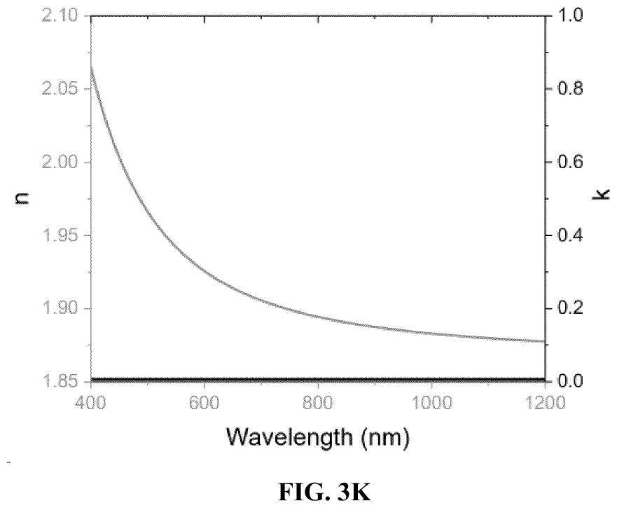

FIG. 3A and FIG. 3B show optical microscopy and SEM characterization of the (silicon) master mold fabricated in the above-mentioned step 210 respectively. FIG. 3C shows optical microscopy characterization of the soft mold fabricated in the above-mentioned step 220 using EVGNIL UV/AF1 as the soft material. FIG. 3D and FIG. 3E show SEM characterization of the soft mold fabricated in the above-mentioned step 220 using EVGNIL UV/AF1 as the soft material. FIG. 3F show optical microscopy characterization of the optic element (e.g. metalens) fabricated in the above-mentioned step 230 using TiO₂ nanoparticle embedded acrylic resin nanocomposite as the nanocomposite material. FIG. 3G to 3J show SEM characterization of the optic element (e.g. metalens) fabricated in the above-mentioned step 230 using TiO₂ nanoparticle embedded acrylic resin nanocomposite as the nanocomposite material. FIG. 3K show a refractive index (n) and an extinction coefficient (k) of the TiO₂ nanoparticle embedded acrylic resin nanocomposite as a function of wavelengths. As shown in FIG. 3K, the refractive index (n) of the TiO₂ nanoparticle embedded acrylic resin nanocomposite is greater than 2 at the wavelength of 400 nm. The refractive index (n) of the TiO₂ nanoparticle embedded acrylic resin nanocomposite decreases as the wavelength increases and is around 1.85 at the wavelength of 1200 nm.

FIG. 3B is an SEM image of the master mold, FIG. 3E shows holes of the soft mold with varying diameters, FIGS. 3I and 3G show nanopillars of the optic element with varying diameters.

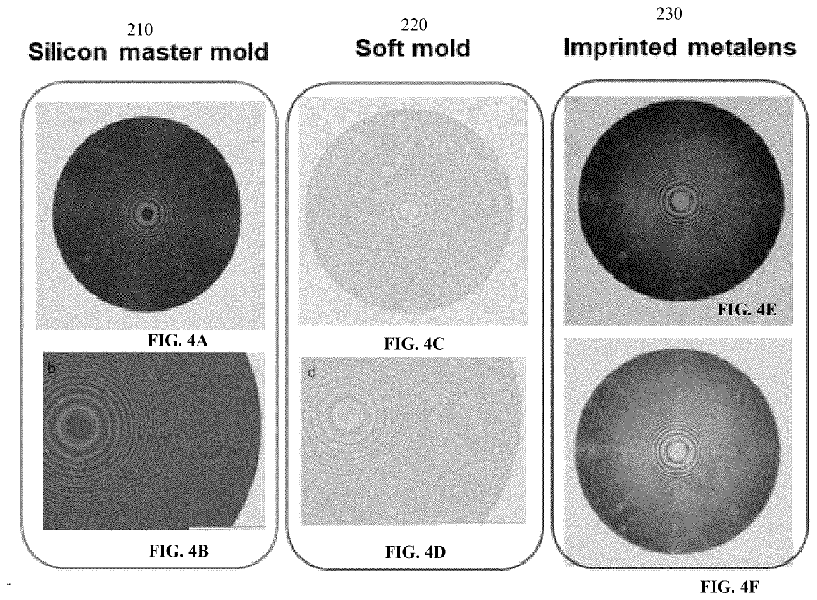

FIG. 4A and FIG. 4B show optical characterization of the master mold fabricated in the above-mentioned step 210. FIG. 4C and FIG. 4D show optical characterization of the soft mold fabricated in the above-mentioned step 220 using GMN-PS380 as the soft material. FIG. 4E and FIG. 4F show reflection optical micrograph and transmission optical micrograph of the optic element (e.g. the metalens) fabricated in the above-mentioned step 230 using the TiO₂ nanoparticle embedded IOC-133 resin nanocomposite as the nanocomposite material.

According to various non-limiting embodiments, the optic element may include nanopillars 310 (as shown in FIG. 3J) on a substrate (e.g. a quartz wafer). The nanopillars 310 may have an aspect ratio which is equal to or greater than 5:1. The nanopillar 310 of the optic element may be periodically repeated along the surface of the substrate in two orthogonal directions to form the optic element (e.g. a metalens including a plurality of unit cells 310). The nanopillar 310 may have a height of 500 nm to 1200 nm, a period of 200 nm to 600 nm, and a diameter of 50 nm to 400 nm. The nanopillar 310 may introduce phase shift in the incident wave depending on the diameter of the nanopillar 310.

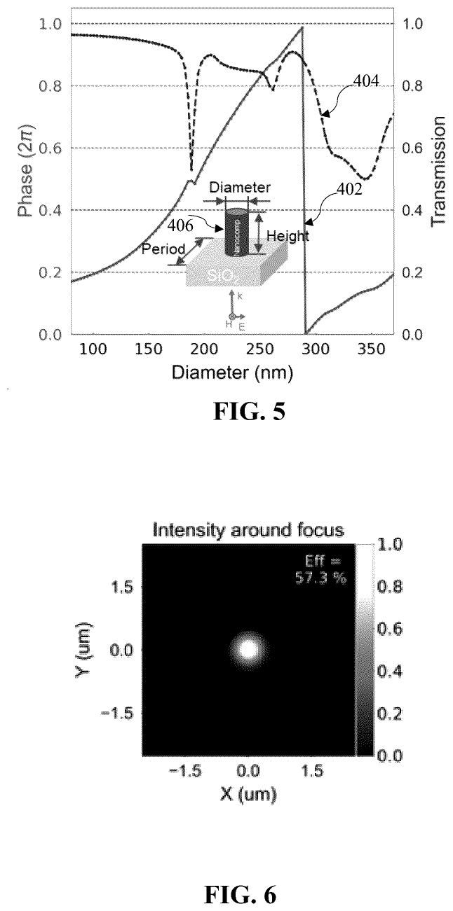

According to various non-limiting embodiments, the pattern of the optic element (e.g., metalens) may be designed using Rigorous coupled-wave analysis (RCWA). The optic element (e.g., metalens) may be designed to impart a phase shift to incident light. The optic element may be designed to include nanopillars 406 (as shown in the inset of FIG. 5) on a substrate (e.g. a quartz wafer). The nanopillar 406 of the designed optic element may be periodically repeated along the surface of the substrate in two orthogonal directions to form the optic element (e.g. a metalens including a plurality of unit cells). The nanopillar 406 may have a height of 810 nm and a period of 450 nm, and the diameter of the nanopillar 406 may vary from 80 to 370 nm. A unit cell (i.e., nanopillar 406) of the designed metalens is shown in the inset of FIG. 5. The nanopillars 406 may introduce phase shift in the incident wave and the phase shifts depend on the diameter of the nanopillar 406. FIG. 5 shows phase shift 402 and transmission 404 of the unit cells as a function of the diameter of the unit cell. Accordingly, the desired diameter of the nanopillar 406 may be determined so as to meet its phase shift and transmission requirements.

A phase distribution or phase profile of the optic element (e.g., metalens) may follow the shape of a hyperbola. The hyperbolic phase profile of the metalens may be discretized and mapped using the nanopillars 406 of the designed optic element (e.g. the metalens). The optic element may have a total lens diameter of 200 μm, focusing at 173 μm, numerical aperture (NA) of about 0.5. FIG. 6 shows point spread function (PSF) of the designed optic element. Resulting focusing is simulated using Fourier transform calculations with the point spread function (PSF) shown in FIG. 6. The simulated focusing efficiency for the optic element is 57.3%.

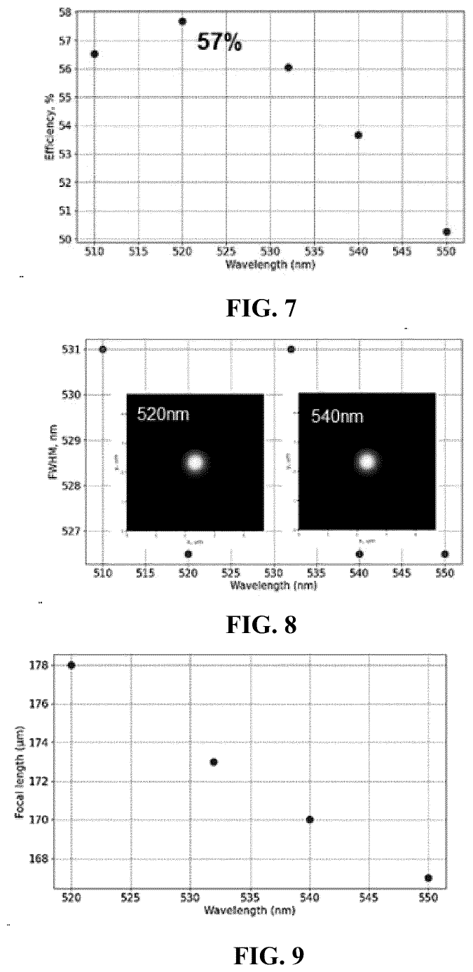

FIGS. 7 to 9 respectively show optical characterization results of focusing efficiency, full width at half maximum (FWHM), and focal length of an optic element (e.g. a metalens) fabricated in accordance with the methods 100, 200 of the present disclosure. NA was 0.5, a focal length was 173 μm, and a metalenses diameter was 200 μm for focusing efficiency calculation. FIG. 7 shows that >56% focusing efficiency of the metalens was measured at 532 nm wavelength for which metalens is designed. FIG. 8 shows that the FWHM of the intensity profile of the metalens remains constant for the wavelength range of 510 nm to 550 nm within detector resolution. FIG. 9 shows the focal length of the metalens for wavelength ranging from 520 nm to 550 nm. Overall, experimental measurements validate that high efficacy metalenses can be achieved in the visible spectrum using the method 100, 200 of fabricating the metalens provided in the present disclosure.

Conventional fabrication methods for metalens and flat optics such as electron-beam lithography (EBL) suffer from low throughput, small patterning area, and thus low cost-effectiveness, limiting the industrial application requiring large-scale and high throughput. The present disclosure provides a fabrication process for metalens via the NIL process, which is scalable using imprinted soft molds made of a photoinitiator material for high throughput production. The present disclosure provides for large area and high throughput fabrication of flat optics with high resolution that is comparable to Electron-beam lithography (EBL).

The refractive index of the conventional NIL resin is intrinsically too low to be employed in high-performance metalenses and flat optics. Conventional metasurfaces consisting of the nanocomposite shows a low focusing efficiency of 33% in the visible spectrum, resulting in a reduction of performance and applicability. NIL resin with a low refractive index (e.g., n<1.7) would require nanopillars of the metalens to have extremely high aspect ratio (HAR) (e.g., >20:1) and with feature resolution <100 nm to realize the high-performance metalens. However, it would be challenging to fabricate metalens with nanopillars that have HAR >20:1 and with feature resolution <100 nm using the NIL technology.

The approach in the present disclosure provides nanocomposite material having a high refractive index (e.g., n>2 for wavelength of 400 nm) and having good imprintability, where nanopillars included in the metalens has a high aspect ratio (HAR) which is equal to or greater than 5:1, a feature resolution of ≤100 nm and the fabricated metalens exhibits high focusing efficiency (>56%). The present disclosure provides a method of fabricating metalenses using NIL using resin embedded with dielectric nanoparticles with high refractive index which increases the refractive index of the nanocomposite and using this high refractive index nanocomposite as the building block materials and directly imprinting the nanocomposite into functional meta-atoms.

In addition, conventional approaches of fabricating metalens utilize hard PDMS (hPDMS) elastomer as the soft material for fabricating a soft mold, which requires multiple steps to fabricate the soft mold. A single-step process to fabricate the soft mold using the soft materials provided in the present disclosure can make the fabrication process more cost-effective and with fewer defects.

The method in the present disclosure can ensure adequate compatibility between the Si master mold and the soft material, and compatibility between the soft material and the nanocomposite material, to facilitate the complete soft material filling, nanocomposite material filling, demolding of the soft mold and cured nanocomposite layer, which ensure a high-fidelity pattern transfer from the master mold to the soft mold, and from the soft mold to the optic element through the NIL process. The size variation between the nanopillars of the master mold and the holes of the soft mold, the size variation between the holes of the soft mold and the nanopillars of the optic element (i.e., the metalens) may be controlled within 10 nm. Adequate compatibility between the soft material and the nanocomposite material may be the pre-requisite of acquiring the optic element.

The optimized NIL conditions ensure an adequate elasticity of the nanocomposite layer after curing. Hence, the nanopillars can be well retained to acquire high yields with minimal defects after the demolding. For example, UV curing of 360 s (in 5 s On/Off cycle) applied to solidify the nanocomposite material in the nanocomposite layer may help to ensure an adequate elasticity of the nanocomposite layer after curing.

While this specification contains many details, these should not be understood as limitations on the scope of what may be claimed, but rather as descriptions of features specific to particular examples. Certain features that are described in this specification or shown in the drawings in the context of separate implementations can also be combined. Conversely, various features that are described or shown in the context of a single implementation can also be implemented in multiple implementations separately or in any suitable sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single product or packaged into multiple products.

A number of implementations have been described. Nevertheless, it will be understood that various modifications can be made. Accordingly, other implementations are within the scope of the following claims.

1. A method for fabricating an optic element, the method comprising:
(i) fabricating a first mold having a pattern of the optic element;
(ii) fabricating a second mold with a soft material by using the first mold, the second mold having an opposite pattern to the pattern of the optic element;
(iii) forming a nanocomposite layer on a substrate, wherein the nanocomposite layer comprises nanoparticles embedded therein, the nanocomposite layer having a refractive index which is equal to or greater than 2;
(iv) placing the second mold onto the nanocomposite layer and curing the nanocomposite layer;
(v) demolding the cured nanocomposite layer from the second mold to obtain the optic element.

2. The method of claim 1, wherein fabricating a first mold having a pattern of the optic element comprises:
applying an etch mask layer on a wafer;
patterning the etch mask layer by electron-beam lithography to form the pattern of the optic element on the etch mask layer; and
etching the wafer through the patterned etch mask layer by deep reactive-ion etching (DRIE) to form the pattern of the optic element in the wafer as the first mold.

3. The method of claim 2, wherein the etch mask layer comprises hydrogen silsesquioxane (HSQ), a NEB-22 resist by Sumitomo Chemical, an AR-N 7520 resist by ALLRESIST GmbH, a maN resist by micro resist technology GmbH or a ZEP resist by Zeon Corporation.

4. The method of claim 1, wherein fabricating a second mold with a soft material by using the first mold comprises:
forming a soft material layer on a stamping substrate, wherein the soft material layer comprises the soft material;
placing the first mold onto the soft material layer and curing the soft material layer; and
demolding the cured soft material layer from the first mold to obtain the second mold.

5. The method of claim 4, wherein fabricating a second mold with a soft material by using the first mold further comprises:
applying pressure on the first mold when the first mold is placed onto the soft material layer.

6. The method of claim 4, wherein forming a soft material layer on a stamping substrate comprises:
forming a first adhesion layer on the stamping substrate; and
forming the soft material layer on the first adhesion layer.

7. The method of claim 1, wherein the soft material comprises an UV curable photoinitiator material.

8. The method of claim 1, wherein the soft material comprises EVGNIL UV/AF1 or GMN-PS380.

9. The method of claim 1, wherein forming a nanocomposite layer on a substrate comprises:
forming a second adhesion layer on the substrate; and
forming the nanocomposite layer on the second adhesion layer.

10. The method of claim 1, wherein the nanocomposite layer comprises titanium dioxide (TiO₂) nanoparticle embedded resin nanocomposites.

11. The method of claim 10, wherein the titanium dioxide (TiO₂) nanoparticle embedded resin nanocomposites have a TiO₂ weight ratio ranging from 75% to 80%.

12. The method of claim 1, wherein the nanocomposite layer is UV curable.

13. The method of claim 1, further comprising applying pressure on the second mold when the second mold is placed onto the nanocomposite layer.

14. The method of claim 1, wherein the optic element comprises a plurality of nanopillars having an aspect ratio which is equal to or greater than 5 to 1.

15. The method of claim 14, wherein a feature resolution of the plurality of nanopillars is equal to or less than 100 nm.

16. The method of claim 14, wherein the plurality of nanopillars has a height ranging from 500 nm to 1200 nm.

17. The method of claim 14, wherein the plurality of nanopillars is periodically repeated along a surface in two orthogonal directions.

18. The method of claim 17, wherein the periodically repeated nanopillars has a period ranging from 200 nm to 600 nm.

19. The method of claim 14, wherein the plurality of nanopillars has a diameter ranging from 50 nm to 400 nm.

20. The method of claim 1, further comprising:
repeating the steps (iii) to (v) to fabricate a plurality of the optic elements having the pattern.
